(19) United States
(12) Patent Application Publication
(10) Pub. No.: US 2026/0012136 A1
(43) Pub. Date: Jan. 8, 2026

(54) TRACKER CIRCUIT, TRACKER MODULE, AND VOLTAGE SUPPLY METHOD

(71) Applicant: Murata Manufacturing Co., Ltd., Nagaokakyo-shi (JP)

(72) Inventors: Takeshi KOGURE, Nagaokakyo-shi (JP); Taichi YAMAGUCHI, Nagaokakyo-shi (JP); Atsuya HIRONO, Nagaokakyo-shi (JP); Naohide TOMITA, Nagaokakyo-shi (JP); Yuuki FUKUDA, Nagaokakyo-shi (JP)

(21) Appl. No.: 19/322,836

(22) Filed: Sep. 9, 2025

Related U.S. Application Data
(63) Continuation of application No. PCT/JP2024/006711, filed on Feb. 26, 2024.

(30) Foreign Application Priority Data
Mar. 27, 2023 (JP) 2023-050644

(51) Int. Cl. H03F 1/02; H03F 3/24

(52) U.S. Cl. CPC H03F 1/0227; H03F 3/245; H03F 2200/102; H03F 2200/105; H03F 2200/451

(57) ABSTRACT

A tracker circuit includes a buck boost converter circuit configured to convert an input voltage V_{IN} to a variable voltage V₁, a buck converter circuit configured to convert the input voltage V_{IN} to a variable voltage V₂ that is lower than the input voltage V_{IN}, and a supply modulator configured to selectively supply at least one discrete voltage of a plurality of discrete voltages including the variable voltages V₁ and V₂ to a power amplifier.

### CROSS REFERENCE TO RELATED APPLICATION

This application is a continuation of International Application No. PCT/JP2024/006711, filed Feb. 26, 2024, which claims priority to Japanese Patent Application No. Application No. 2023-050644, filed Mar. 27, 2023, the contents of each of which are hereby incorporated by reference in their entireties.

### TECHNICAL FIELD

The present disclosure relates to a tracker circuit, a tracker module, and a voltage supply method.

### BACKGROUND

In U.S. Pat. No. 8,829,993, by applying a digital envelope tracking (ET) mode for supplying a plurality of discrete voltages to a power amplifier, power efficiency can be improved.

However, in the digital ET mode, reduction in power consumption and size reduction are desired.

### SUMMARY OF THE INVENTION

To address this, the exemplary aspects of the present disclosure provide for a tracker circuit, a tracker module, and a voltage supply method with reduced power consumption and size reduction.

Thus, according to an exemplary aspect, a tracker circuit is provided that includes a buck boost converter circuit configured to convert an input voltage to a first adjustment voltage; a buck converter circuit configured to convert the input voltage to a second adjustment voltage lower than the input voltage; and a supply modulator configured to selectively supply at least one discrete voltage of a plurality of discrete voltages including the first adjustment voltage and the second adjustment voltage to a first power amplifier.

In another exemplary aspect, a tracker module is provided that includes a first module laminate different from a substrate where a switch included in a first converter circuit is arranged. In this aspect, the first converter circuit is configured to convert an input voltage to a first adjustment voltage; a second converter circuit is configured to convert the input voltage to a second adjustment voltage; and a supply modulator is configured to selectively supply at least one discrete voltage of a plurality of discrete voltages including the first adjustment voltage and the second adjustment voltage to a first power amplifier. Moreover, a switch included in the second converter circuit and a switch included in the supply modulator are arranged on the first module laminate.

In yet another exemplary aspect, a voltage supply method is provided that includes converting an input voltage to a first adjustment voltage; converting the input voltage to a second adjustment voltage lower than the input voltage; and selectively outputting at least one discrete voltage of a plurality of discrete voltages including the first adjustment voltage and the second adjustment voltage to a first power amplifier, based on an envelope signal.

According to the exemplary aspects of the tracker circuit, tracker module and voltage supply method described herein, reduction in power consumption and size reduction is provided.

### BRIEF DESCRIPTION OF DRAWINGS

FIG. 1A is a graph depicting one example of transitions of power supply voltage in an APT mode.

FIG. 1B is a graph depicting one example of transitions of power supply voltage in an analog ET mode.

FIG. 1C is a graph depicting one example of transitions of power supply voltage in a digital ET mode.

FIG. 2 is a diagram of the circuit structure of a communication device according to a first exemplary embodiment.

FIG. 3 is a diagram of the circuit structure of a tracker circuit according to the first exemplary embodiment.

FIG. 4 is a flowchart depicting a voltage supply method according to the first exemplary embodiment.

FIG. 5 is a diagram of the structure of a first tracker module and a second tracker module according to the first exemplary embodiment.

FIG. 6 is a plan view of the first tracker module according to the first exemplary embodiment.

FIG. 7 is a plan view of the second tracker module according to the first exemplary embodiment.

FIG. 8 is a diagram of the mounting structure of the communication device according to the first exemplary embodiment.

FIG. 9 is a diagram of the circuit structure of a communication device according to a second exemplary embodiment.

FIG. 10 is a flowchart depicting a voltage supply method according to the second exemplary embodiment.

FIG. 11 is a diagram of the mounting structure of the communication device according to the second exemplary embodiment.

### DETAILED DESCRIPTION OF EMBODIMENTS

Exemplary embodiments of the present disclosure are described in detail below by using the drawings. The embodiments described below each describe a comprehensive or specific example. Numerical values, shapes, materials, components, the arrangement and connection types of the components, and so forth described in the embodiments below are merely examples and are not intended to restrict the present disclosure.

It is noted that each drawing is a schematic drawing with enhancement, omission, or ratio adjustment as appropriate to describe the exemplary aspects of the present disclosure and is not necessarily strictly depicted, and the shapes, positional relation, and ratio may be different from actual ones. In each drawing, substantially identical structures are provided with the same reference character and redundant description of these may be omitted or simplified.

In each drawing below, an x axis and a y axis are axes orthogonal to each other on a plane parallel to a principal surface of a substrate. Specifically, when a substrate has a rectangular shape in plan view, the x axis is parallel to a first side of the substrate, and the y axis is parallel to a second side orthogonal to the first side of the substrate. Also, a z axis is an axis perpendicular to the principal surface of the substrate, and its positive direction indicates an upward direction and its negative direction indicates a downward direction.

In the arrangement of components of the exemplary aspects of the present disclosure, the phrase “plan view of a substrate” indicates that an object or component is viewed in orthographic projection from a z-axis positive side to an xy plane. The phrase “A overlaps B in plan view” can indicate that at least part of a region of A orthographically projected to the xy plane overlaps at least part of a region of B orthographically projected to the xy plane. Also, the phrase “A is arranged between B and C” can indicate that at least one of a plurality of line segments connecting any point in B and any point in C passes through A.

In the arrangement of components of the exemplary aspects of the present disclosure, the phrase “a component is arranged on a substrate” includes that a component is arranged on a principal surface of a substrate and that a component is arranged in a substrate. Moreover, the phrase “A component is arranged on a principal surface of a substrate” includes that, in addition to that a component is arranged in contact with a principal surface of a substrate, a component is arranged above the principal surface not in contact with the principal surface (for example, a component is laminated on another component arranged in contact with the principal surface). Also, the phrase “a component is arranged on a principal surface of a substrate” may include that a component is arranged in a recessed part formed in a principal surface. The phrase “a component is arranged in a substrate” includes that, in addition to that a component is encapsulated in a module laminate, the entire component is arranged between principal surfaces of a substrate but part of the component is not covered with the substrate and that only part of the component is arranged in the substrate.

In the circuit structure of the present disclosure, the term “connected” can include not only a direct connection with a connection terminal and/or wiring conductor but also an electrical connection via another circuit element. Moreover, the phrase “connected between A and B” can indicate connected to both A and B between A and B.

Also, in the present disclosure, the phrase “component (element) A is arranged in series to a path B” can indicate that both of the signal input end and the signal output end of the component (element) A are connected to a wire, electrode, or terminal configuring the path B.

Also, in the component arrangement of the exemplary aspects of the present disclosure, the phrase “A is adjacently arranged to B” represents that A and B are arranged nearby and, specifically, can indicate that another circuit component is not present in a space where A faces B. In other words, the phrase “A is adjacently arranged to B” can indicate that any of a plurality of line segments reaching B from any point on a plane where A faces B along a normal direction of that plane does not pass through a circuit component other than A and B. Here, the circuit component refers to a component including an active element and/or passive element. That is, in the circuit component, an active component including a transistor, a diode, or the like and a passive component including an inductor, a transformer, a capacitor, a resistor, or the like are included, and an electromechanical component including a terminal, a connector, a wire, or the like is not included.

According to the exemplary aspects of the present disclosure, the term “terminal” refers to a point where a conductor in the component ends. It is also noted that when impedance of a conductor between components is sufficiently low, the terminal can be construed as not only a single point but also any point on the conductor between components or the whole conductor.

Also, terms such as “parallel” and “perpendicular” indicating a relation between components, terms such as “rectangular” indicating a shape of component, and a range of numerical values each do not represent only a strict meaning, but also include an error in a substantially equivalent range, for example, on the order of several percent.

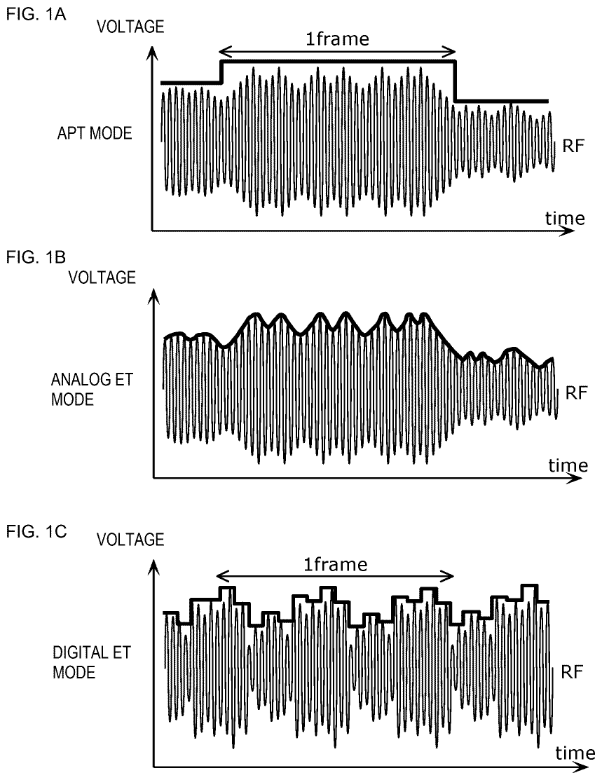

First, as a technology for efficiently amplifying a radio frequency signal, tracking modes are described for supplying, to a power amplifier, a power supply voltage dynamically adjusted with an elapse of time based on a radio frequency signal. A tracking mode is a mode for dynamically adjusting a power supply voltage to be applied to a power amplifier. There are several types of tracking modes. Here, an average power tracking (APT) mode and an envelope tracking (ET) mode (including an analog ET mode and a digital ET mode) are described with reference to FIG. 1A to FIG. 1C. In FIG. 1A to FIG. 1C, the horizontal axis represents time and the vertical axis represents voltage. Also, a bold solid line represents power supply voltage and a thin solid line (waveform) represents a modulated signal.

FIG. 1A is a graph depicting one example of transitions of power supply voltage in an APT mode. In the APT mode, the power supply voltage fluctuates at a plurality of discrete voltage levels in the unit of one frame, based on average power. As a result, the power supply voltage signal forms a rectangular wave.

According to an exemplary aspect, a frame can refer to a unit configuring a radio frequency signal (modulated signal). For example, in 5th Generation New Radio (5GNR) and Long Term Evolution (LTE), a frame includes ten subframes, each subframe includes a plurality of slots, and each slot is configured of a plurality of symbols. The subframe length is 1 ms, and the frame length is 10 ms.

It is noted that a mode for fluctuating a voltage level in the unit of one frame or a larger unit based on average power is called an APT mode to be distinguished from a mode for fluctuating a voltage level in a unit smaller than one frame (for example, subframe, slot, or symbol).

FIG. 1B is a graph depicting one example of transitions of power supply voltage in an analog ET mode. In the analog ET mode, the power supply voltage successively fluctuates based on an envelope signal, thereby causing an envelope of a modulated signal to be tracked.

The envelope signal is a signal indicating an envelope of a modulated signal. An envelope value is represented as, for example, the square root of (I²+Q²). Here, (I, Q) represents a constellation point. The constellation point is a point for representing a signal modulated by digital modulation on a constellation diagram. (I, Q) is determined based on, for example, transmission information, by, for example, a baseband integrated circuit (BBIC).

FIG. 1C is a graph depicting one example of transitions of power supply voltage in a digital ET mode. In the digital ET mode, based on the envelope signal, the power supply voltage fluctuates at a plurality of discrete voltage levels in one frame, thereby causing the envelope of the modulated signal to be tracked. As a result, the power supply voltage signal forms a rectangular wave.

### First Exemplary Embodiment

A first embodiment is described below.

### 1.1 Circuit Structure of Communication Device 6

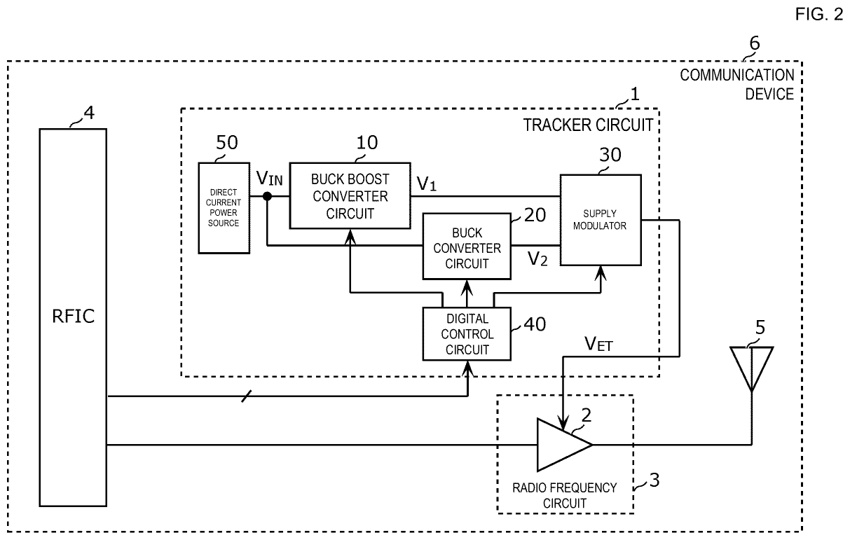

First, a communication device 6 according to the present embodiment is described with reference to FIG. 2. FIG. 2 is a diagram of the circuit structure of the communication device 6 according to the present embodiment.

It is noted that FIG. 2 is an exemplary circuit structure and the communication device 6 can be mounted by using any of a wide variety of circuit implementations and circuit technologies. Therefore, description of the communication device 6 provided below is not to be construed as restrictive.

The communication device 6 corresponds to user equipment (UE) in a cellular network and is, typically, a mobile phone, a smartphone, a tablet computer, a wearable device, or the like. It is noted that the communication device 6 may be an Internet of Things (IoT) sensor device, a medical/healthcare device, a vehicle, an unmanned aerial vehicle (UAV) (a so-called drone), or an automated guided vehicle (AGV) in exemplary aspects. Also, the communication device 6 may be configured to function as a base station (BS) in a cellular network.

As depicted in FIG. 2, the communication device 6 includes a tracker circuit 1, a radio frequency circuit 3, a radio frequency integrated circuit (RFIC) 4, and an antenna 5.

The tracker circuit 1 can supply a plurality of discrete voltages to a power amplifier 2 in a digital ET mode. As depicted in FIG. 2, the tracker circuit 1 includes a buck boost converter circuit 10, a buck converter circuit 20, a supply modulator 30, a digital control circuit 40, and a direct current power source 50.

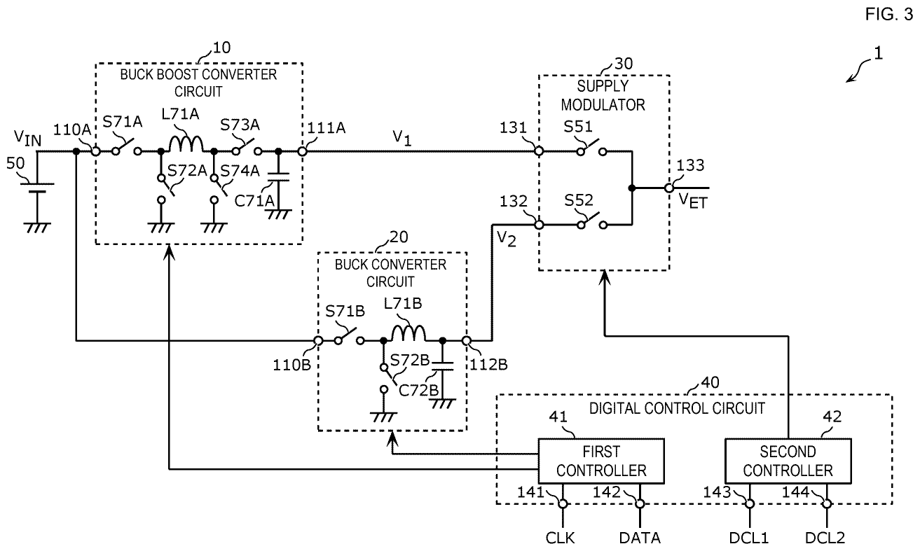

The buck boost converter circuit 10 is one example of a first converter circuit and is a one-input one-output buck boost converter. The buck boost converter circuit 10 can convert an input voltage V_{IN} supplied from the direct current power source 50 to one variable voltage V₁ (first adjustment voltage). The buck boost converter circuit 10 can change the variable voltage V₁ based on, for example, a control signal from the RFIC 4. The buck boost converter circuit 10 can convert the input voltage V_{IN} to the variable voltage V₁ higher than the input voltage V_{IN} and the variable voltage V₁ lower than the input voltage V_{IN}. The circuit structure of the buck boost converter circuit 10 will be described below by using FIG. 3.

The buck converter circuit 20 is one example of a second converter circuit and is a one-input one-output buck converter. The buck converter circuit 20 can convert the input voltage V_{IN} supplied from the direct current power source 50 to one variable voltage V₂ (second adjustment voltage). The buck converter circuit 20 can change the variable voltage V₂ based on, for example, a control signal from the RFIC 4. The buck converter circuit 20 can convert the input voltage V_{IN} to the variable voltage V₂ lower than the input voltage V_{IN}. It is noted that the buck converter circuit 20 cannot convert the input voltage V_{IN} to a variable voltage higher than the input voltage V_{IN}. The circuit structure of the buck converter circuit 20 will be described below by using FIG. 3.

The supply modulator 30 can selectively supply at least one of a plurality of discrete voltages including the variable voltage V₁ generated at the buck boost converter circuit 10 and the variable voltage V₂ generated at the buck converter circuit 20 to the power amplifier 2. That is, the supply modulator 30 can select at least one voltage from among the plurality of discrete voltages and output the selected voltage to the power amplifier 2. The circuit structure of the supply modulator 30 will be described below by using FIG. 3.

The digital control circuit 40 can control the buck boost converter circuit 10, the buck converter circuit 20, and the supply modulator 30, based on a digital control signal from the RFIC 4. Specifically, the digital control circuit 40 can generate and output a control signal for controlling a switch included in the buck boost converter circuit 10, a control signal for controlling a switch included in the buck converter circuit 20, and a control signal for controlling a switch included in the supply modulator 30. The circuit structure of the digital control circuit 40 will be described below by using FIG. 3.

The direct current power source 50 can supply power supply voltage (input voltage) to the buck boost converter circuit 10 and the buck converter circuit 20. As the direct current power source 50, for example, a rechargeable battery can be used, but this is not restrictive. It is noted that the digital control circuit 40 and the direct current power source 50 may be omitted from the tracker circuit 1 in an exemplary aspect.

The radio frequency circuit 3 can transfer a radio frequency signal between the RFIC 4 and the antenna 5. As depicted in FIG. 2, the radio frequency circuit 3 includes the power amplifier 2.

The power amplifier 2 is connected between the RFIC 4 and the antenna 5. Furthermore, the power amplifier 2 is connected to the tracker circuit 1. By using a plurality of discrete voltages received from the tracker circuit 1, the power amplifier 2 can amplify a radio frequency signal received from the RFIC 4. It is noted that the radio frequency circuit 3 may include a filter connected between the power amplifier 2 and the antenna 5 and having a pass band including a predetermined band.

The predetermined band is a frequency band for a communication system constructed by using a radio access technology (RAT), and is defined in advance by a standardizing body or the like (for example, 3rd Generation Partnership Project (3GPP)®, Institute of Electrical and Electronics Engineers (IEEE), or the like). Examples of the communication system can include a 5GNR system, an LTE system, a wireless local area network (WLAN) system, and so forth.

The antenna 5 transmits a radio frequency signal inputted from the radio frequency circuit 3. It is noted that the antenna 5 may be omitted from the communication device 6 in an exemplary aspect.

It is noted that the circuit structure of the communication device 6 depicted in FIG. 2 is merely an example and is not restrictive. For example, the communication device 6 may include a baseband signal processing circuit for performing signal processing by using an intermediate frequency band lower than that of the radio frequency signal.

### 1.2 Circuit Structure of Tracker Circuit 1

Next, the circuit structure of the tracker circuit 1 is described with reference to FIG. 3. FIG. 3 is a diagram of the circuit structure of the tracker circuit 1 according to the first embodiment.

It is noted that FIG. 3 is an exemplary circuit structure and the tracker circuit 1 can be mounted by using any of a wide variety of circuit implementations and circuit technologies. Therefore, description of each circuit provided below is not to be construed as restrictive.

According to an exemplary aspect, the tracker circuit 1 includes, as described above, the buck boost converter circuit 10, the buck converter circuit 20, the supply modulator 30, the digital control circuit 40, and the direct current power source 50. It is noted that the tracker circuit 1 may include a filter circuit (not depicted) between the supply modulator 30 and the power amplifier 2 in an exemplary aspect.

The circuit structures of the buck boost converter circuit 10, the buck converter circuit 20, the supply modulator 30, and the digital control circuit 40 are sequentially described below.

### 1.2.1 Circuit Structure of Buck Boost Converter Circuit 10

The buck boost converter circuit 10 includes an input terminal 110A, an output terminal 111A, switches S71A, S72A, S73A, and S74A, a power inductor L71A, and a capacitor C71A.

The input terminal 110A is one example of a first input terminal and is a terminal for receiving the input voltage V_{IN} from the direct current power source 50. The input terminal 110A is connected to the direct current power source 50 outside the buck boost converter circuit 10 and is connected to the switch S71A inside the buck boost converter circuit 10.

The output terminal 111A is one example of a first output terminal and is a terminal for supplying the variable voltage V₁ to the supply modulator 30. The output terminal 111A is connected to an input terminal 131 (first terminal) of the supply modulator 30 outside the buck boost converter circuit 10 and is connected to the switch S73A inside the buck boost converter circuit 10.

The power inductor L71A is one example of a first power inductor and is an inductor for use in increasing and decreasing the direct-current voltage. The input end of the power inductor L71A is connected to the switches S71A and S72A, and the output end of the power inductor L71A is connected to the switches S73A and S74A.

The switch S71A is one example of a first switch and is connected between the input terminal 110A and the input end of the power inductor L71A. Specifically, the switch S71A includes a terminal connected to the input terminal 110A and a terminal connected to the input end of the power inductor L71A. In this connection structure, with ON/OFF being switched, the switch S71A can switch connection and non-connection between the input terminal 110A and the input end of the power inductor L71A.

The switch S72A is one example of a second switch and is connected between the input end of the power inductor L71A and the ground. Specifically, the switch S72A includes a terminal connected to the input end of the power inductor L71A and a terminal connected to the ground. In this connection structure, with ON/OFF being switched, the switch S72A can switch connection and non-connection between the input end of the power inductor L71A and the ground.

The switch S73A is one example of a third switch and is connected between the output end of the power inductor L71A and the output terminal 111A. Specifically, the switch S73A includes a terminal connected to the output end of the power inductor L71A and a terminal connected to the output terminal 111A. In this connection structure, with ON/OFF being switched, the switch S73A can switch between connection and non-connection between the output end of the power inductor L71A and the output terminal 111A.

The switch S74A is one example of a fourth switch and is connected between the output end of the power inductor L71A and the ground. Specifically, the switch S74A includes a terminal connected to the output end of the power inductor L71A and a terminal connected to the ground. In this connection structure, with ON/OFF being switched, the switch S74A can switch between connection and non-connection between the output end of the power inductor L71A and the ground.

The capacitor C71A is one example of a first capacitor and is connected between a path between the switch S73A and the output terminal 111A and the ground. Specifically, one of two electrodes of the capacitor C71A is connected to the switch S73A and the output terminal 111A, and the other one of the two electrodes of the capacitor C71A is connected to the ground.

The buck boost converter circuit 10 configured as described above can convert the input voltage V_{IN} to the variable voltage V₁.

It is noted that the structure of the buck boost converter circuit 10 depicted in FIG. 3 is merely an example and is not restrictive. For example, one or some of the switches S71A to S74A may be replaced by a diode in an alterative aspect. Also, the structure of the buck boost converter circuit 10 is merely an example and is not restrictive. For example, the buck boost converter circuit 10 may be a charge pump circuit that can increase and decrease voltage, the charge pump circuit not including the power inductor L71A but configured of a capacitor and a switch.

### 1.2.2 Circuit Structure of Buck Converter Circuit 20

The buck converter circuit 20 includes an input terminal 110B, an output terminal 112B, switches S71B and S72B, a power inductor L71B, and a capacitor C72B.

The input terminal 110B is one example of a second input terminal and is a terminal for receiving the input voltage V_{IN} from the direct current power source 50. The input terminal 110B is connected to the direct current power source 50 outside the buck converter circuit 20 and is connected to the switch S71B inside the buck converter circuit 20.

The output terminal 112B is one example of a second output terminal and is a terminal for supplying the variable voltage V₂ to the supply modulator 30. The output terminal 112B is connected to an input terminal 132 (second terminal) of the supply modulator 30 outside the buck converter circuit 20 and is connected to the power inductor L71B inside the buck converter circuit 20.

The power inductor L71B is one example of a second power inductor and is an inductor for use in increasing and decreasing the direct-current voltage. The input end of the power inductor L71B is connected to the switches S71B and S72B, and the output end of the power inductor L71B is connected to the output terminal 112B.

The switch S71B is one example of a fifth switch and is connected between the input terminal 110B and the input end of the power inductor L71B. Specifically, the switch S71B includes a terminal connected to the input terminal 110B and a terminal connected to the input end of the power inductor L71B. In this connection structure, with ON/OFF being switched, the switch S71B can switch connection and non-connection between the input terminal 110B and the input end of the power inductor L71B.

The switch S72B is one example of a sixth switch and is connected between the input end of the power inductor L71B and the ground. Specifically, the switch S72B includes a terminal connected to the input end of the power inductor L71B and a terminal connected to the ground. In this connection structure, with ON/OFF being switched, the switch S72B can switch connection and non-connection between the input end of the power inductor L71B and the ground.

The capacitor C72B is one example of a second capacitor and is connected between a path between the power inductor L71B and the output terminal 112B and the ground. Specifically, one of two electrodes of the capacitor C72B is connected to the power inductor L71B and the output terminal 112B, and the other one of the two electrodes of the capacitor C72B is connected to the ground.

The buck converter circuit 20 configured as described above can convert the input voltage V_{IN} to the variable voltage V₂ lower than the input voltage V_{IN}.

It is noted that the structure of the buck converter circuit 20 depicted in FIG. 3 is merely an example and is not restrictive. For example, one of the switches S71B and S72B may be replaced by a diode in an alterative aspect. Also, the structure of the buck converter circuit 20 is merely an example and is not restrictive. For example, the buck converter circuit 20 may be a charge pump circuit that can decrease voltage, the charge pump circuit not including the power inductor L71B but configured of a capacitor and a switch.

### 1.2.3 Circuit Structure of Supply Modulator 30

Next, the circuit structure of the supply modulator 30 is described with reference to FIG. 3. The supply modulator 30 includes the input terminals 131 and 132, switches S51 and S52, and an output terminal 133.

The input terminal 131 is one example of a first terminal and is a terminal for receiving the variable voltage V₁ of the buck boost converter circuit 10. The input terminal 132 is one example of a second terminal and is a terminal for receiving the variable voltage V₂ of the buck converter circuit 20. The input terminal 131 is connected to the output terminal 111A of the buck boost converter circuit 10 outside the supply modulator 30 and is connected to the switch S51 inside the supply modulator 30. The input terminal 132 is connected to the output terminal 112B of the buck converter circuit 20 outside the supply modulator 30 and is connected to the switch S52 inside the supply modulator 30.

The output terminal 133 is a terminal for selectively supplying at least one of a plurality of discrete voltages to the power amplifier 2. The output terminal 133 is connected to the power amplifier 2 outside the supply modulator 30 and is connected to the switches S51 and S52 inside the supply modulator 30. It is noted that the output terminal 133 is connected to the power amplifier 2 not via another circuit component in an exemplary aspect.

The switch S51 is connected between the input terminal 131 and the output terminal 133. Specifically, the switch S51 includes a terminal connected to the input terminal 131 and a terminal connected to the output terminal 133. In this connection structure, with ON/OFF being switched by a control signal based on an envelope signal from the digital control circuit 40, the switch S51 can switch connection and non-connection between the input terminal 131 and the output terminal 133.

The switch S52 is connected between the input terminal 132 and the output terminal 133. Specifically, the switch S52 includes a terminal connected to the input terminal 132 and a terminal connected to the output terminal 133. In this connection structure, with ON/OFF being switched by a control signal based on an envelope signal from the digital control circuit 40, the switch S52 can switch connection and non-connection between the input terminal 132 and the output terminal 133.

In the present embodiment, based on the envelope signal, the switches S51 and S52 are controlled so as to be exclusively turned ON. That is, only either one of the switches S51 and S52 is turned ON, and the other one of the switches S51 and S52 is turned OFF. With this configuration, the supply modulator 30 can output one voltage selected from the variable voltages V₁ and V₂ to the power amplifier 2.

It is noted that the structure of the supply modulator 30 depicted in FIG. 3 is merely an example and is not restrictive. In particular, it is sufficient that the switches S51 and S52 can selectively connect at least one of the two input terminals 131 and 132 to the output terminal 133, and the switches S51 and S52 may have any structure and may be controlled in any manner. For example, both of the switches S51 and S52 may be turned ON.

It is noted that when three or more discrete voltages are supplied from the buck boost converter circuit 10 and the buck converter circuit 20, the supply modulator 30 may further include one or more switches in addition to the switches S51 and S52.

### 1.2.4 Circuit Structure of Digital Control Circuit 40

Next, the circuit structure of the digital control circuit 40 is described with reference to FIG. 3. The digital control circuit 40 includes a first controller 41 and a second controller 42, and control terminals 141 to 144.

The first controller 41 can be configured to process a source-synchronous digital control signal (serial data signal) received from the RFIC 4 via the control terminals 141 and 142 and can generate a control signal for controlling the buck boost converter circuit 10 and the buck converter circuit 20. ON/OFF of the switches S71A, S72A, S73A, and S74A included in the buck boost converter circuit 10 and the switches S71B and S72B included in the buck converter circuit 20 is controlled by the control signal from the first controller 41. That is, the buck boost converter circuit 10 converts the input voltage V_{IN} to the variable voltage V₁ by following the serial data signal. Also, the buck converter circuit 20 converts the input voltage V_{IN} to the variable voltage V₂ by following the serial data signal.

It is noted that the digital control signal processed at the first controller 41 is not limited to a source-synchronous digital control signal. For example, the first controller 41 may be configured to process a clock-embedded digital control signal. Also, the first controller 41 may be configured to generate a control signal for controlling the supply modulator 30.

Also, while one set of a clock signal and a data signal is used in the present embodiment, this is not meant to be restrictive. For example, as a digital control signal, a plurality of sets of a clock signal and a data signal may be used.

The second controller 42 can be configured to process digital control logic/line (DCL) signals (DCL1 and DCL2: parallel data signals) received from the RFIC 4 via the control terminals 143 and 144 and generates a control signal for controlling the supply modulator 30. The DCL signals (DCL1 and DCL2) are generated by the RFIC 4 based on an envelope signal, which is a radio frequency signal. ON/OFF of the switches S51 and S52 included in the supply modulator 30 is controlled by the control signal from the second controller 42. That is, the supply modulator 30 selects at least one of the plurality of discrete voltages by following the parallel data signals.

According to an exemplary aspect, each of the DCL signals (DCL1 and DCL2) is a one-bit signal. Moreover, each of the plurality of discrete voltages including the variable voltages V₁ and V₂ is represented by a combination of two one-bit signals. For example, three discrete voltages are each represented by “00”, “01”, and “10”. For the representation of a voltage level, Gray code may be used.

It is noted that while two digital control logic/line signals are used for control of the supply modulator 30 in the present embodiment, the number of digital control logic/line signals is not limited to this number. For example, one or any number of three or more digital control logic/line signals may be used in accordance with the number of voltage levels that can be selected by each supply modulator 30. Also, the digital control signal for use in control of the supply modulator 30 is not limited to a digital control logic/line signal.

A tracker circuit of related art for supplying a power supply voltage V_{ET} in a digital ET mode has a buck boost converter circuit, a switched-capacitor circuit, and a supply modulator. Having a plurality of flying capacitors and a plurality of switches for complementarily performing charging and discharging in a plurality of phases, the switched-capacitor circuit has a large circuit size and also large power consumption compared with the buck boost converter circuit and the buck converter circuit.

By contrast, as a structure for supplying the power supply voltage V_{ET} to the power amplifier 2 in a digital ET mode according to an exemplary aspect, the tracker circuit 1 according to the present embodiment has the buck boost converter circuit 10, the buck converter circuit 20, and the supply modulator 30, and does not have a switched-capacitor circuit. Thus, according to the tracker circuit 1 of the present embodiment, size reduction and reduction in power consumption is achieved.

### 1.3 Voltage Supply Method

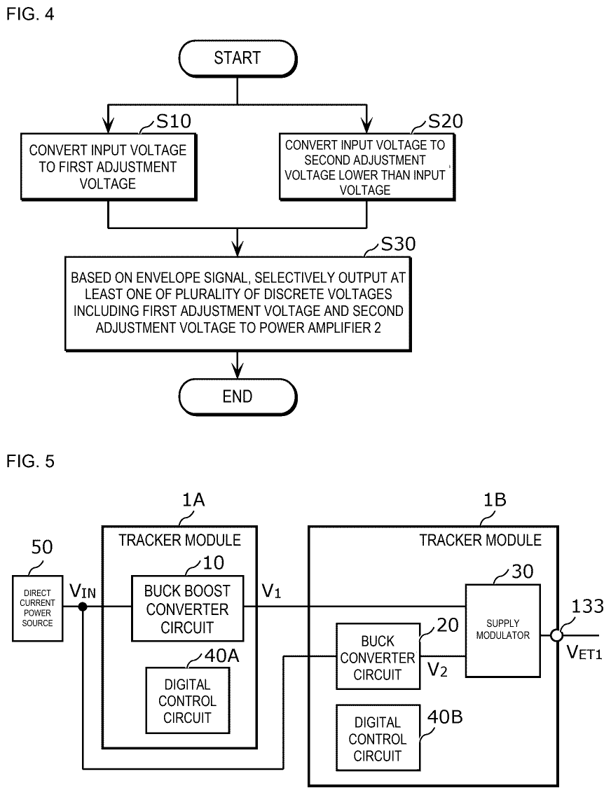

Next, a voltage supply method, which is a method of supplying a plurality of discrete voltages by the tracker circuit 1 configured as described above, is described with reference to FIG. 4. FIG. 4 is a flowchart depicting the voltage supply method according to the present embodiment.

First, the buck boost converter circuit 10 converts the input voltage V_{IN} to the variable voltage V₁ (S10).

Also, the buck converter circuit 20 converts the input voltage V_{IN} to the variable voltage V₂ lower than the input voltage V_{IN} (S20).

Next, the supply modulator 30 selectively outputs at least one of a plurality of discrete voltages including the variable voltages V₁ and V₂ to the power amplifier 2, based on an envelope signal (S30).

According to this configuration, not by using a switched-capacitor circuit but by the buck boost converter circuit 10, the buck converter circuit 20, and the supply modulator 30, the tracker circuit 1 according to the present embodiment can supply the power supply voltage V_{ET} in a digital ET mode to the power amplifier 2. Thus, size reduction and reduction in power consumption of the tracker circuit 1 is achieved.

### 1.4 Mounting Structure of Tracker Circuit 1

FIG. 5 is a diagram of the structure of tracker modules 1A and 1B according to the first embodiment. As depicted in the drawing, the tracker circuit 1 is configured of the tracker modules 1A and 1B and the direct current power source 50.

The tracker module 1A is one example of a second tracker module and includes the buck boost converter circuit 10 (first converter circuit) and a digital control circuit 40A.

The digital control circuit 40A controls the buck boost converter circuit 10 based on a digital control signal from the RFIC 4. Specifically, the digital control circuit 40A generates and outputs a control signal for controlling a switch included in the buck boost converter circuit 10. The digital control circuit 40A includes, for example, the first controller 41 of the digital control circuit 40 depicted in FIG. 3. It is noted that the digital control circuit 40A may be arranged in the tracker module 1B instead of the tracker module 1A in an exemplary aspect.

The tracker module 1B is one example of a first tracker module and includes the buck converter circuit 20 (second converter circuit), the supply modulator 30, and a digital control circuit 40B.

The digital control circuit 40B controls the buck converter circuit 20 and the supply modulator 30 based on a digital control signal from the RFIC 4. Specifically, the digital control circuit 40B generates and outputs a control signal for controlling a switch included in the buck converter circuit 20 and a control signal for controlling a switch included in the supply modulator 30. The digital control circuit 40B includes, for example, the first controller 41 and the second controller 42 of the digital control circuit 40 depicted in FIG. 3. It is noted that the digital control circuit 40B may be omitted from the tracker module 1B in an exemplary aspect.

In the tracker module 1A, the circuit components configuring the buck boost converter circuit 10 and the digital control circuit 40A are arranged on one substrate. Also, in the tracker module 1B, the circuit components configuring the buck converter circuit 20, the supply modulator 30, and the digital control circuit 40B are arranged on a first module laminate different from a substrate configuring the tracker module 1A. It is noted that the substrate configuring the tracker module 1A may be a motherboard where the tracker module 1B and the direct current power source 50 are arranged. That is, the circuit components configuring the tracker module 1A may be arranged directly on the motherboard.

A power supply voltage VEmi is supplied to the power amplifier 2 via the output terminal 133, which is an external connection terminal of the tracker module 1B.

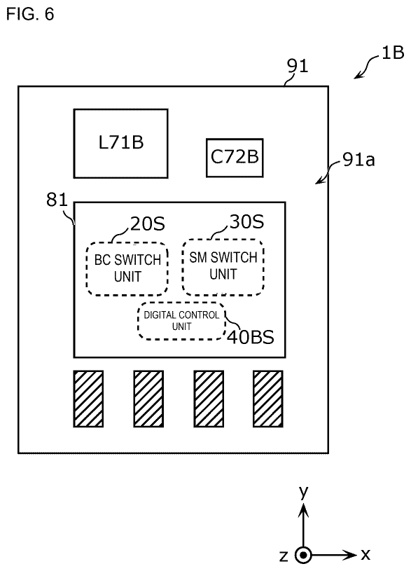

FIG. 6 is a plan view of the tracker module 1B according to the first embodiment. It is noted that in FIG. 6, wires connecting a plurality of circuit components arranged on a module laminate 91 are omitted. Also, in FIG. 6, depiction of a resin member and a shield electrode layer arranged on a principal surface 91a of the module laminate 91 is omitted. It is also noted that the resin member and the shield electrode layer may be omitted. Also, in FIG. 6, hatched blocks each represent any optional circuit component according to exemplary aspects of the present disclosure.

The tracker module 1B includes, as depicted in FIG. 6, the module laminate 91 and an integrated circuit 81.

The module laminate 91 is one example of the first module laminate and has the principal surface 91a. In the module laminate 91 and on the principal surface 91a, a ground plane or the like is formed. It is noted that in FIG. 6, while the module laminate 91 has a rectangular shape in plan view, the shape of the module laminate 91 is not limited to this shape.

As the module laminate 91, for example, a low temperature co-fired ceramics (LTCC) substrate or a high temperature co-fired ceramics (HTCC) substrate having a multilayer structure of a plurality of dielectric layers, a component-embedded board, a substrate having a redistribution layer (RDL), a printed circuit board, or the like can be used, but these are not restrictive.

The integrated circuit 81 is one example of a first integrated circuit, and one of the integrated circuits configuring the tracker circuit 1. The integrated circuit 81 is arranged on the principal surface 91a of the module laminate 91, and has a BC switch unit 20S, an SM switch unit 30S, and a digital control unit 40BS. The BC switch unit 20S includes the switches S71B and S72B of the buck converter circuit 20. The SM switch unit 30S includes the switches S51 and S52 of the supply modulator 30. The digital control unit 40BS includes the digital control circuit 40B.

It is noted that the integrated circuit 81 is only required to include at least one switch included in the buck converter circuit 20 and at least one switch included in the supply modulator 30, and may omit the digital control unit 40BS in an exemplary aspect.

Also, in FIG. 6, while the integrated circuit 81 has a rectangular shape in plan view of the module laminate 91, the shape of the integrated circuit 81 is not limited to this shape.

The integrated circuit 81 may be configured by using, for example, a complementary metal oxide semiconductor (CMOS) and, specifically, may be manufactured by silicon on insulator (SOI) process. It is noted that the integrated circuit 81 is not limited to the CMOS as would be appreciated to one skilled in the art.

It is noted that the tracker module 1B further includes the power inductor L71B and the capacitor C72B included in the buck converter circuit 20.

The power inductor L71B and the capacitor C72B are arranged on the principal surface 91a.

Since the tracker circuit 1 according to the present embodiment does not include a switched-capacitor circuit, the number of components of the tracker modules 1A and 1B configuring the tracker circuit 1 can be reduced and the area of the tracker modules 1A and 1B can be reduced. From this point of view, component mounting density of the tracker module 1B can be lowered. Thus, even when the power inductor L71B with a large amount of heat and in a large size is arranged on the module laminate 91, the size of the tracker module 1B can be reduced without degrading heat dissipation capability.

It is noted that the power inductor L71B may be arranged outside the tracker module 1B.

In an exemplary aspect, the capacitor C72B is mounted as a chip capacitor, which can be a surface mount device (SMD) configuring a capacitor. However, it is noted that the capacitor C72B is not limited to a chip capacitor and, for example, may be included in an integrated passive device (IPD) or may be included in the integrated circuit 81.

It is noted that at least one of the integrated circuit 81, the capacitor C72B, and the power inductor L71B may be arranged inside the module laminate 91 or on a principal surface opposed to the principal surface 91a.

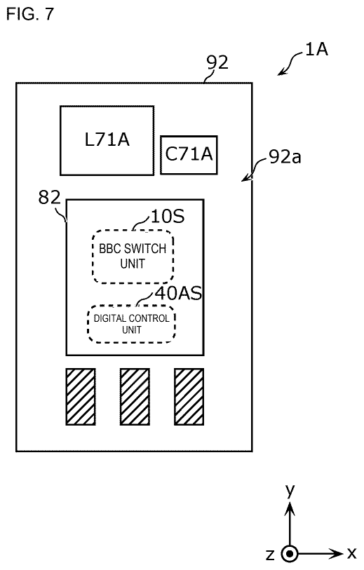

FIG. 7 is a plan view of the tracker module 1A according to the first embodiment. It is noted that in FIG. 7, wires connecting a plurality of circuit components arranged on a module laminate 92 are omitted. Also, in FIG. 7, depiction of a resin member and a shield electrode layer arranged on a principal surface 92a of the module laminate 92 is omitted. It is also noted that the resin member and the shield electrode layer may be omitted in an exemplary aspect. Also, in FIG. 7, hatched blocks each represent any optional circuit component according to exemplary aspects of the present disclosure.

The tracker module 1A includes, as depicted in FIG. 7, the module laminate 92 and an integrated circuit 82.

The integrated circuit 82 is one example of a second integrated circuit, and one of the integrated circuits configuring the tracker circuit 1. The integrated circuit 82 is arranged on the principal surface 92a of the module laminate 92 and has a BBC switch unit 10S and a digital control unit 40AS. The BBC switch unit 10S includes S71A, S72A, S73A, and S74A of the buck boost converter circuit 10. The digital control unit 40AS includes the digital control circuit 40A.

It is noted that the integrated circuit 82 is only required to include at least one switch included in the buck boost converter circuit 10, and may omit the digital control unit 40AS in an exemplary aspect. Also, the integrated circuit 82 is not arranged on the module laminate 91. That is, the tracker module 1A and the tracker module 1B are separate bodies.

It is noted that in FIG. 7, while the integrated circuit 82 has a rectangular shape in plan view of the module laminate 92, the shape of the integrated circuit 82 is not limited to this shape as would be appreciated to one skilled in the art.

As the module laminate 92, for example, an LTCC substrate or an HTCC substrate having a multilayer structure of a plurality of dielectric layers, a component-embedded board, a substrate having an RDL, a printed circuit board, or the like can be used, but these are not restrictive.

The integrated circuit 82 may be configured by using, for example, a CMOS and, specifically, may be manufactured by SOI process. It is noted that the integrated circuit 82 is not limited to a CMOS as would be appreciated to one skilled in the art.

It is noted that the tracker module 1A further includes the power inductor L71A and the capacitor C71A included in the buck boost converter circuit 10.

Since the tracker circuit 1 according to the present embodiment does not include a switched-capacitor circuit, the number of components of the tracker modules 1A and 1B configuring the tracker circuit 1 can be reduced and the area of the tracker modules 1A and 1B can be reduced. From this point of view, component mounting density of the tracker module 1A can be lowered. Thus, even when the power inductor L71A with a large amount of heat and in a large size is arranged on the module laminate 92, the size of the tracker module 1A can be reduced without degrading heat dissipation capability.

The power inductor L71A and the capacitor C71A are arranged on the principal surface 92a. It is noted that the power inductor L71A may be arranged outside the tracker module 1A in an exemplary aspect.

The capacitor C71A is mounted as a chip capacitor, which can be an SMD configuring a capacitor. However, it is noted that the capacitor C71A is not limited to a chip capacitor and, for example, may be included in an IPD or may be included in the integrated circuit 82.

It is noted that the integrated circuit 82 may be arranged inside the module laminate 92 or on a principal surface opposed to the principal surface 92a in various exemplary aspects.

### 1.5 Mounting Structure of Communication Device 6

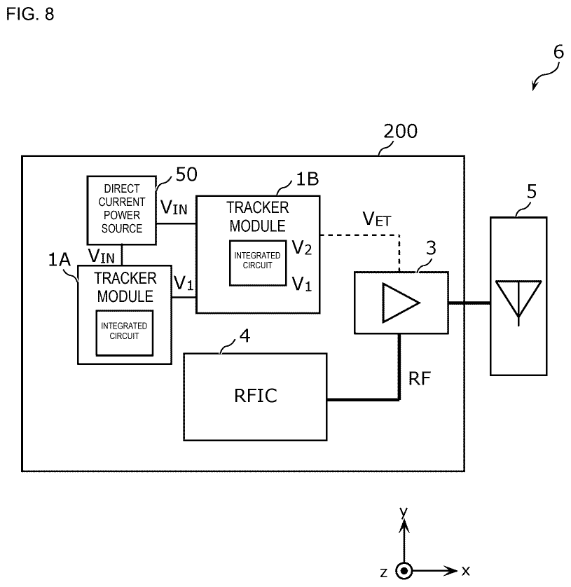

FIG. 8 is a diagram of the mounting structure of the communication device 6 according to the first embodiment. It is noted that in FIG. 8, wires connecting a plurality of circuit components arranged on a motherboard 200 are omitted. Also, in FIG. 8, depiction of a resin member and a shield electrode layer arranged on a principal surface of the motherboard 200 is omitted. It is also noted that the resin member and the shield electrode layer may be omitted according to exemplary aspects.

As depicted in FIG. 8, the communication device 6 includes the motherboard 200, the RFIC 4, the radio frequency circuit 3, the tracker modules 1A and 1B, and the direct current power source 50.

On the motherboard 200, the RFIC 4, the radio frequency circuit 3, the tracker modules 1A and 1B, and the direct current power source 50 are arranged. The motherboard 200 is a substrate different from the module laminates 91 and 92. On an inner side and on a principal surface of the motherboard 200, a ground plane or the like is formed. It is noted that in FIG. 8, while the motherboard 200 has a rectangular shape in plan view, the shape of the motherboard 200 is not limited to this shape as would be appreciated to one skilled in the art.

As the motherboard 200, for example, an LTCC substrate or an HTCC substrate having a multilayer structure of a plurality of dielectric layers, a component-embedded board, a substrate having an RDL, a printed circuit board, or the like can be used, but these are not restrictive.

As depicted in FIG. 8, the antenna 5 is arranged on a right side (x-axis positive direction) of the motherboard 200. It is noted that the antenna 5 may be arranged on the motherboard 200 in an exemplary aspect.

As depicted in FIG. 8, the tracker module 1B is arranged closer to the radio frequency circuit 3 than the tracker module 1A.

According to this configuration, since a wire connecting the tracker module 1B and the power amplifier 2 can be shortened, degradation in efficiency of the tracker circuit 1 in a digital ET mode can be minimized while also suppressing an increase in power consumption of the tracker circuit 1.

It is noted that the tracker module 1B and the power amplifier 2 are desired to be adjacently arranged. According to this configuration, since a wire connecting the tracker module 1B and the power amplifier 2 can be further shortened, degradation in efficiency of the tracker circuit 1 can further be minimized.

Also, the RFIC 4 and the radio frequency circuit 3 are desired to be adjacently arranged. According to this configuration, since a radio frequency transmission line connecting the RFIC 4 and the power amplifier 2 can be further shortened, transmission losses with a radio frequency signal can be reduced.

### 1.6 Technical Effects

As described above, the tracker circuit 1 according to the present embodiment includes the buck boost converter circuit 10 configured to convert the input voltage V_{IN} to the variable voltage V₁, the buck converter circuit 20 configured to convert the input voltage V_{IN} to the variable voltage V₂ lower than the input voltage V_{IN}, and the supply modulator 30 configured to selectively supply at least one of a plurality of discrete voltages including the variable voltages V₁ and V₂ to the power amplifier 2.

According to this configuration, as a structure for supplying the power supply voltage V_{ET} to the power amplifier 2 in a digital ET mode, the tracker circuit 1 has the buck boost converter circuit 10, the buck converter circuit 20, and the supply modulator 30, and does not have a switched-capacitor circuit. Thus, according to the tracker circuit 1 of the present embodiment, size reduction and reduction in power consumption is achieved.

Also, for example, in the tracker circuit 1 according to the present embodiment, the buck boost converter circuit 10 includes the power inductor L71A.

According to this configuration, the stable variable voltage V₁ can be generated without being influenced by fluctuations of the input voltage V_{IN}.

Also, for example, in the tracker circuit 1 according to the present embodiment, the buck boost converter circuit 10 is configured to convert the input voltage V_{IN} to the variable voltage V₁ by following a serial data signal, the buck converter circuit 20 is configured to convert the input voltage V_{IN} to the variable voltage V₂ by following a serial data signal, and the supply modulator 30 is configured to select at least one of the plurality of discrete voltages by following a parallel data signal.

According to this configuration, since the supply modulator 30 operates by following the parallel data signal, the supply modulator 30 in a digital ET mode can be operated at high speeds. Therefore, in the digital ET mode, followability of the power supply voltage V_{ET} with respect to the envelope can be improved, and power-added efficiency of the power amplifier 2 is improved.

Also, for example, in the tracker circuit 1 according to the present embodiment, the buck boost converter circuit 10 includes the power inductor L71A, the input terminal 110A receiving the input voltage V_{IN}, the output terminal 111A connected to the input terminal 131 of the supply modulator 30, the switch S71A connected between the input end of the power inductor L71A and the input terminal 110A, the switch S72A connected between the input end of the power inductor L71A and ground, the switch S73A connected between the output end of the power inductor L71A and the output terminal 111A, the switch S74A connected between the output end of the power inductor L71A and the ground, and the capacitor C71A connected between a path between the switch S73A and the output terminal 111A and the ground.

According to this configuration, since the variable voltage V₁, which is one of the plurality of discrete voltages, can be generated by a step-up/down circuit configured of one power inductor, four switches, and one capacitor, the structure of the tracker circuit 1 is simplified.

Also, for example, in the tracker circuit 1 according to the present embodiment, the buck converter circuit 20 includes the power inductor L71B, the input terminal 110B receiving the input voltage V_{IN}, the output terminal 112B connected to the input terminal 132 of the supply modulator 30, the switch S71B connected between the input end of the power inductor L71B and the input terminal 110B, the switch S72B connected between the input end of the power inductor L71B and the ground, and the capacitor C72B connected between a path between the power inductor L71B and the output terminal 112B and the ground.

According to this configuration, since the variable voltage V₂, which is one of the plurality of discrete voltages, can be generated by a step-down circuit configured of one power inductor, two switches, and one capacitor, the structure of the tracker circuit 1 is simplified.

Also, the tracker module 1B according to the present embodiment includes the module laminate 91 different from the module laminate 92 where switches included in a first converter circuit configured to convert the input voltage V_{IN} to the variable voltage V₁ is arranged, a second converter circuit configured to convert the input voltage V_{IN} to the variable voltage V₂, and the supply modulator 30 configured to selectively supply at least one of a plurality of discrete voltages including the variable voltages V₁ and V₂ to the power amplifier 2. Switches included in the buck converter circuit 20 and switches included in the supply modulator 30 are arranged on the module laminate 91.

According to this configuration, as a structure for supplying the power supply voltage V_{ET} to the power amplifier 2 in the digital ET mode, the tracker module 1B has the second converter circuit and the supply modulator 30 and does not have a switched-capacitor circuit. Thus, according to the tracker module 1B of the present embodiment, size reduction and reduction in power consumption is achieved.

Also, for example, in the tracker modules 1A and 1B, the first converter circuit is the buck boost converter circuit 10, the second converter circuit is the buck converter circuit 20, and the variable voltage V₂ is lower than the input voltage V_{IN}.

Also, for example, in the tracker module 1B, at least one switch included in the buck converter circuit 20 and at least one switch included in the supply modulator 30 are included in the integrated circuit 81, and the integrated circuit 81 is arranged on the module laminate 91.

According to this configuration, since the switch configuring the tracker module 1B is included in the integrated circuit 81, the size of the tracker module 1B is further reduced.

Also, for example, in the tracker module 1B, the second converter circuit includes the power inductor L71B, and the power inductor L71B is arranged on the module laminate 91.

Since the tracker circuit 1 according to the present embodiment does not include a switched-capacitor circuit, the number of components of the tracker modules 1A and 1B configuring the tracker circuit 1 can be reduced and the area of the tracker modules 1A and 1B can be reduced. From this point of view, component mounting density of the tracker module 1B can be lowered. Thus, even when the power inductor L71B with a large amount of heat and in a large size is arranged on the module laminate 91, the size of the tracker module 1B can be reduced without degrading heat dissipation capability.

Also, the voltage supply method according to the present embodiment converts the input voltage V_{IN} to the variable voltage V₁ (S10), converts the input voltage V_{IN} to the variable voltage V₂ lower than the input voltage V_{IN} (S20), and selectively outputs at least one of the plurality of discrete voltages including the variable voltages V₁ and V₂ to the power amplifier 2, based on an envelope signal (S30).

According to this configuration, not by using a switched-capacitor circuit but by the buck boost converter circuit 10, the buck converter circuit 20, and the supply modulator 30, the tracker circuit 1 according to the present embodiment can supply the power supply voltage V_{ET} in the digital ET mode to the power amplifier 2. Thus, size reduction and reduction in power consumption of the tracker circuit 1 is achieved.

### Second Exemplary Embodiment

Next, a second embodiment is described. The present embodiment is different from the first embodiment mainly in that the buck boost converter circuit 10 supplies a power supply voltage V_{APT} in an APT mode to the power amplifier. The point of the present embodiment different from the first embodiment is mainly described below with reference to the drawings.

### 2.1 Circuit Structure of Communication Device 9

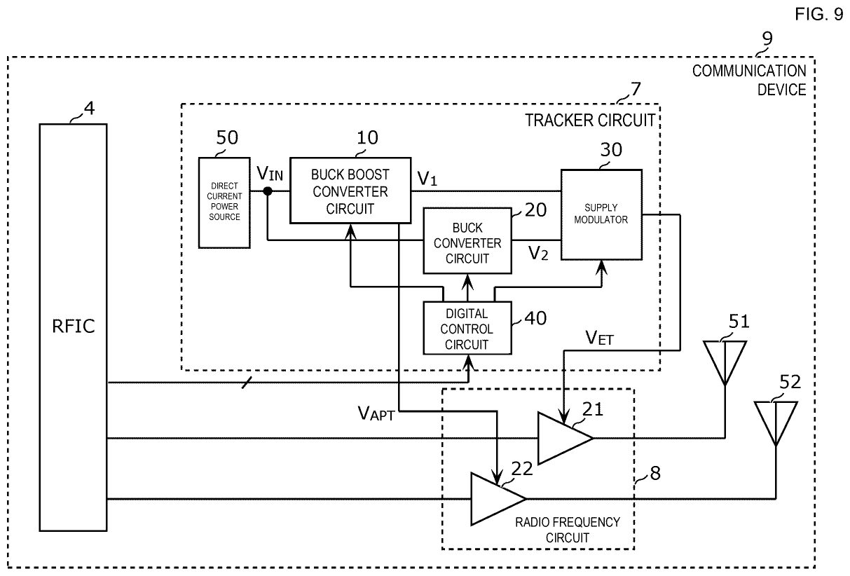

A communication device 9 according to the present embodiment is described with reference to FIG. 9. FIG. 9 is a diagram of the circuit structure of the communication device 9 according to the present second embodiment.

It is noted that FIG. 9 is an exemplary circuit structure and the communication device 9 can be mounted by using any of a wide variety of circuit implementations and circuit technologies. Therefore, description of the communication device 9 provided below is not to be construed as restrictive.

The communication device 9 according to the present embodiment includes a tracker circuit 7, a radio frequency circuit 8, the RFIC 4, and antennas 51 and 52.

The tracker circuit 7 can supply a plurality of discrete voltages to a power amplifier 21 in a digital ET mode and supply a power supply voltage to a power amplifier 22 in the APT mode. As depicted in FIG. 9, the tracker circuit 7 includes the buck boost converter circuit 10, the buck converter circuit 20, the supply modulator 30, the digital control circuit 40, and the direct current power source 50. The tracker circuit 7 according to the present embodiment is different compared with the tracker circuit 1 according to the first embodiment in that the power supply voltage V_{APT} is supplied from the buck boost converter circuit 10 to the power amplifier 22 in the APT mode. Therefore, the circuit structures of the buck boost converter circuit 10, the buck converter circuit 20, the supply modulator 30, and the digital control circuit 40 are identical to the circuit structures of the buck boost converter circuit 10, the buck converter circuit 20, the supply modulator 30, and the digital control circuit 40 configuring the tracker circuit 1 according to the first embodiment, and therefore description of these circuit structures is omitted.

As depicted in FIG. 9, the buck boost converter circuit 10 is configured to supply the variable voltage V₁ to the power amplifier 22 not via the supply modulator 30.

The radio frequency circuit 8 can transfer a radio frequency signal between the RFIC 4 and the antennas 51 and 52. As depicted in FIG. 9, the radio frequency circuit 8 includes the power amplifiers 21 and 22.

The power amplifier 21 is one example of a first power amplifier and is connected between the RFIC 4 and the antenna 51. Also, the power amplifier 22 is one example of a second power amplifier and is connected between the RFIC 4 and the antenna 52. Furthermore, the power amplifier 21 is connected to the supply modulator 30 of the tracker circuit 7, and the power amplifier 22 is connected to the buck boost converter circuit 10 of the tracker circuit 7. With this configuration, by using a plurality of discrete voltages including the variable voltages V₁ and V₂ received from the tracker circuit 7, the power amplifier 21 can amplify the radio frequency signal received from the RFIC 4. Also, by using the variable voltage V₁ received from the tracker circuit 7, the power amplifier 22 can amplify the radio frequency signal received from the RFIC 4. It is noted that the radio frequency circuit 8 may include a filter connected between the power amplifier 21 and the antenna 51 and having a pass band including a predetermined band, and may also include a filter connected between the power amplifier 22 and the antenna 52 and having a pass band including a predetermined band.

The antenna 51 transmits the radio frequency signal inputted from the power amplifier 21, and the antenna 52 transmits the radio frequency signal inputted from the power amplifier 22. It is noted that the antennas 51 and 52 may be omitted from the communication device 9 in an exemplary aspect.

According to this configuration, the tracker circuit 7 can supply the power supply voltage V_{APT} in the APT mode to the power amplifier 22 by the buck boost converter circuit 10. Also, not by using a switched-capacitor circuit but by using the buck boost converter circuit 10 for use in the APT mode and the buck converter circuit 20 and the supply modulator 30, the tracker circuit 7 can supply the power supply voltage V_{ET} in the digital ET mode to the power amplifier 21. Thus, the tracker circuit 7 configured for supporting both the APT mode and the digital ET mode in a small size and with low power consumption is provided.

### 2.2 Voltage Supply Method

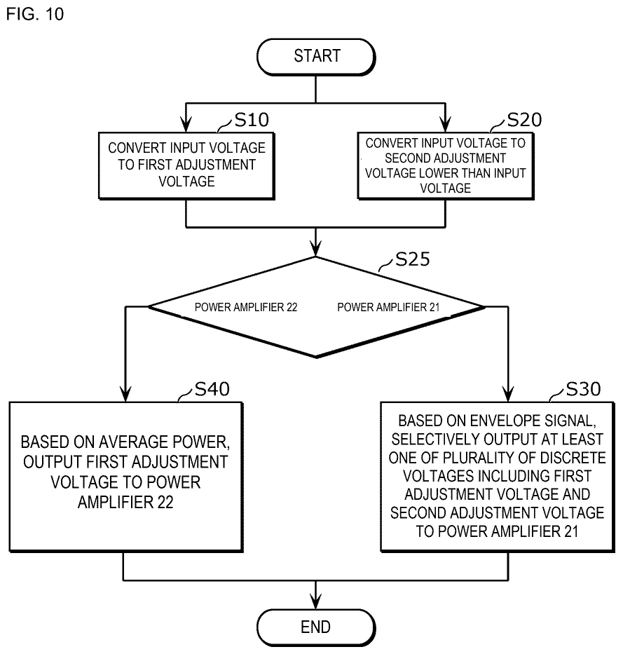

Next, a voltage supply method, which is a method of supplying the power supply voltages V_{ET} and V_{APT} by the tracker circuit 7 configured as described above, is described with reference to FIG. 10. FIG. 10 is a flowchart depicting the voltage supply method according to the present embodiment.

First, the buck boost converter circuit 10 converts the input voltage V_{IN} to the variable voltage V₁ (S10).

Also, the buck converter circuit 20 converts the input voltage V_{IN} to the variable voltage V₂ lower than the input voltage V_{IN} (S20).

Next, when the power supply voltage V_{ET} is supplied to the power amplifier 21 (power amplifier 21 at S25), the supply modulator 30 selectively outputs at least one of the plurality of discrete voltages including the variable voltages V₁ and V₂ to the power amplifier 21, based on an envelope signal (S30).

Also, when the power supply voltage V_{APT} is supplied to the power amplifier 22 (power amplifier 22 at S25), the buck boost converter circuit 10 outputs the variable voltage V₁ to the power amplifier 22, based on average power corresponding to an input signal or output signal of the power amplifier 22 (S40).

According to this configuration, the tracker circuit 7 according to the present embodiment can supply the power supply voltage V_{APT} in the APT mode to the power amplifier 22 by the buck boost converter circuit 10. Also, not by using a switched-capacitor circuit but by using the buck boost converter circuit 10 for use in the APT mode and the buck converter circuit 20 and the supply modulator 30, the tracker circuit 7 can supply the power supply voltage V_{ET} in the digital ET mode to the power amplifier 21. Thus, the tracker circuit 7 capable of supporting both the APT mode and the digital ET mode in a small size and with low power consumption is provided.

It is noted that when the predetermined band of the radio frequency signal to be transferred through a first transmission path including the power amplifier 21 is on a high frequency side of the predetermined band of the radio frequency signal to be transferred through a second transmission path including the power amplifier 22, the tracker circuit 7 may supply the power supply voltage VEr in the digital ET mode to the power amplifier 21 and supply the power supply voltage V_{APT} in the APT mode to the power amplifier 22.

According to this configuration, transmission losses of the radio frequency signal in the first transmission path are larger than transmission losses of the radio frequency signal in the second transmission path. By contrast, power-added efficiency can be enhanced in the power amplifier 21 to which the digital ET mode is applied more than the power amplifier 22 to which the APT mode is applied, and thus power consumption of the communication device 9 can be reduced, and degradation in signal quality is suppressed.

Also, when maximum transmission power of a radio frequency signal to be transferred through the first transmission path including the power amplifier 21 is larger than maximum transmission power of a radio frequency signal to be transferred through the second transmission path including the power amplifier 22, the tracker circuit 7 may supply the power supply voltage V_{ET} in the digital ET mode to the power amplifier 21 and may supply the power supply voltage V_{APT} in the APT mode to the power amplifier 22.

According to this configuration, transmission losses of the radio frequency signal in the first transmission path are larger than transmission losses of the radio frequency signal in the second transmission path. By contrast, power-added efficiency can be enhanced in the power amplifier 21 to which the digital ET mode is applied more than the power amplifier 22 to which the APT mode is applied, and thus power consumption of the communication device 9 can be reduced, and degradation in signal quality is suppressed.

### 2.3 Mounting Structure of Communication Device 9

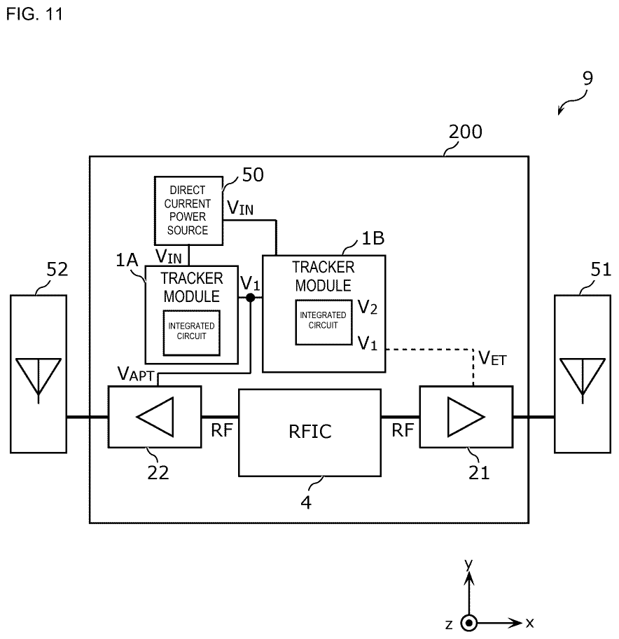

FIG. 11 is a diagram of the mounting structure of the communication device 9 according to the second embodiment. It is noted that in FIG. 11, wires connecting a plurality of circuit components arranged on the motherboard 200 are omitted. Also, in FIG. 11, depiction of a resin member and a shield electrode layer arranged on a principal surface of the motherboard 200 is omitted. It is also noted that the resin member and the shield electrode layer may be omitted according to exemplary aspects.

The communication device 9 includes, as depicted in FIG. 11, the motherboard 200, the RFIC 4, the power amplifiers 21 and 22, the tracker modules 1A and 1B, and the direct current power source 50.

On the motherboard 200, the RFIC 4, the power amplifiers 21 and 22, the tracker modules 1A and 1B, and the direct current power source 50 are arranged. The motherboard 200 is a substrate different from the module laminates 91 and 92.

As depicted in FIG. 11, the antenna 51 is arranged on a right side (x-axis positive direction) of the motherboard 200, and the antenna 52 is arranged on a left side (x-axis negative direction) of the motherboard 200. It is noted that the antennas 51 and 52 may be arranged on the motherboard 200.

As depicted in FIG. 11, the tracker module 1B is arranged closer to the power amplifier 21 than the tracker module 1A. According to this configuration, since a wire connecting the tracker module 1B and the power amplifier 21 can be shortened, degradation in efficiency of the tracker circuit 7 in the digital ET mode can be minimized while also suppressing an increase in power consumption of the tracker circuit 7.

It is noted that the tracker module 1B and the power amplifier 21 are desired to be adjacently arranged. According to this configuration, since a wire connecting the tracker module 1B and the power amplifier 21 can be further shortened, degradation in efficiency of the tracker circuit 7 can also be reduced or prevented.

Also, the tracker module 1A is arranged closer to the power amplifier 22 than the tracker module 1B. According to this configuration, since a wire connecting the tracker module 1A and the power amplifier 22 can be shortened, degradation in efficiency of the tracker circuit 7 in the APT mode can be suppressed while also suppressing an increase in power consumption of the tracker circuit 7.

Also, the power amplifier 21 is arranged near the antenna 51, and the power amplifier 22 is arranged near the antenna 52. Furthermore, the RFIC 4 is desired to be arranged between the power amplifiers 21 and 22. According to this configuration, since a radio frequency transmission line connecting the RFIC 4 and the power amplifier 21 and a radio frequency transmission line connecting the RFIC 4 and the power amplifier 22 can be further shortened, transmission losses with a radio frequency signal can be reduced.

### 2.4 Technical Effects

As described above, the tracker circuit 7 according to the present embodiment includes the buck boost converter circuit 10 configured to convert the input voltage V_{IN} to the variable voltage V₁, the buck converter circuit 20 configured to convert the input voltage V_{IN} to the variable voltage V₂ lower than the input voltage V_{IN}, and the supply modulator 30 configured to selectively supply at least one of a plurality of discrete voltages including the variable voltages V₁ and V₂ to the power amplifier 21. The buck boost converter circuit 10 is configured to supply the variable voltage V₁ to the power amplifier 22 not via the supply modulator 30.

According to this configuration, the tracker circuit 7 can supply the power supply voltage V_{APT} in the APT mode to the power amplifier 22 by the buck boost converter circuit 10. Also, not by using a switched-capacitor circuit but by using the buck boost converter circuit 10 for use in the APT mode and the buck converter circuit 20 and the supply modulator 30, the tracker circuit 7 can supply the power supply voltage V_{ET} in the digital ET mode to the power amplifier 21. Thus, the tracker circuit 7 capable of supporting both the APT mode and the digital ET mode in a small size and with low power consumption is provided.

Also, the voltage supply method according to the present embodiment converts the input voltage V_{IN} to the variable voltage V₁ (S10), converts the input voltage V_{IN} to the variable voltage V₂ lower than the input voltage V_{IN} (S20), selectively outputs at least one of the plurality of discrete voltages including the variable voltages V₁ and V₂ to the power amplifier 21 based on an envelope signal (S30) and, also outputs the variable voltage V₁ to the power amplifier 22 based on average power (S40).

According to this configuration, the power supply voltage V_{APT} in the APT mode can be supplied to the power amplifier 22 by the buck boost converter circuit 10. Also, not by using a switched-capacitor circuit but by using the buck boost converter circuit 10 for use in the APT mode and the buck converter circuit 20 and the supply modulator 30, the power supply voltage V_{ET} in the digital ET mode can be supplied to the power amplifier 21. Thus, the tracker circuit 7 capable of supporting both the APT mode and the digital ET mode in a small size and with low power consumption is provided.

### Additional Exemplary Embodiments

While the tracker circuit, the tracker module, and the voltage supply method according to the exemplary aspects of the present disclosure have been described above based on the embodiments, it is noted that the tracker circuit, the tracker module, and the voltage supply method described herein are not restricted to the above-described embodiments. Another exemplary embodiment can be achieved by combining any components in the above-described embodiments, a modification can be obtained by applying various modifications understandable to those persons skilled in the art to any of the above-described embodiments in a range not deviating from the gist of the exemplary aspects, and various devices having the above-described tracker circuit and tracker module incorporated therein can be included in the present disclosure.

For example, in the circuit structure of any of various circuits according to the above-described embodiments, another circuit element, wire, or the like may be inserted into a path connecting each circuit element and a signal path disclosed in the drawings. For example, an inductor and/or capacitor may be inserted between the tracker circuit 1 and the power amplifier 2.

Finally, it is noted that the tracker circuit 1 and/or 7 according to the above-described embodiments may include a plurality of supply modulators. In this case, the tracker circuit 1 and/or 7 can supply a different voltage to each of the plurality of power amplifiers.

The exemplary aspects of the present disclosure can be widely used for a communication device such as a mobile phone as a tracker circuit for supplying voltage to a power amplifier.

### REFERENCE SIGNS LIST

1, 7 tracker circuit
1A, 1B tracker module
2, 21, 22 power amplifier
3, 8 radio frequency circuit
4 RFIC
5, 51, 52 antenna
6, 9 communication device
10 buck boost converter circuit
10S BBC switch unit
20 buck converter circuit
20S BC switch unit
30 supply modulator
30S SM switch unit
40, 40A, 40B digital control circuit
40AS, 40BS digital control unit
41 first controller
42 second controller
50 direct current power source
81, 82 integrated circuit
91, 92 module laminate
91a, 92a principal surface
110A, 110B, 131, 132 input terminal
111A, 112B, 133 output terminal
141, 142, 143, 144 control terminal
200 motherboard

What is claimed:

1. A tracker circuit comprising:
a buck boost converter circuit configured to convert an input voltage to a first adjustment voltage;
a buck converter circuit configured to convert the input voltage to a second adjustment voltage lower than the input voltage; and
a supply modulator configured to selectively supply at least one discrete voltage of a plurality of discrete voltages that includes the first adjustment voltage and the second adjustment voltage to a first power amplifier.

2. The tracker circuit according to claim 1, wherein the buck boost converter circuit includes a power inductor.

3. The tracker circuit according to claim 1, wherein:
the buck boost converter circuit is configured to convert the input voltage to the first adjustment voltage by following a serial data signal,
the buck converter circuit is configured to convert the input voltage to the second adjustment voltage by following a serial data signal, and
the supply modulator is configured to select the at least one discrete voltage by following a parallel data signal.

4. The tracker circuit according to claim 1, wherein the buck boost converter circuit is configured to supply the first adjustment voltage to a second power amplifier not via the supply modulator.

5. The tracker circuit according to claim 1, wherein the buck boost converter circuit includes:
a first power inductor,
a first input terminal configured to receive the input voltage,
a first output terminal connected to a first terminal of the supply modulator,
a first switch connected between an input end of the first power inductor and the first input terminal,
a second switch connected between the input end of the first power inductor and ground,
a third switch connected between an output end of the first power inductor and the first output terminal,
a fourth switch connected between the output end of the first power inductor and the ground, and
a first capacitor connected between a path between the third switch and the first output terminal and the ground.

6. The tracker circuit according to claim 1, wherein the buck converter circuit includes:
a second power inductor,
a second input terminal configured to receive the input voltage,
a second output terminal connected to a second terminal of the supply modulator,
a fifth switch connected between an input end of the second power inductor and the second input terminal,
a sixth switch connected between the input end of the second power inductor and ground, and
a second capacitor connected between a path between the second power inductor and the second output terminal and the ground.

7. A tracker module comprising:
a first module laminate that is different from a substrate where a switch included in a first converter circuit is arranged, the first converter circuit being configured to convert an input voltage to a first adjustment voltage;
a second converter circuit configured to convert the input voltage to a second adjustment voltage; and
a supply modulator configured to selectively supply to a first power amplifier at least one discrete voltage of a plurality of discrete voltages that includes the first adjustment voltage and the second adjustment voltage,
wherein each of the second converter circuit and the supply modulator include a switch that is arranged on the first module laminate.

8. The tracker module according to claim 7, wherein the first converter circuit is a buck boost converter circuit, and the second converter circuit is a buck converter circuit.

9. The tracker module according to claim 8, wherein the second adjustment voltage is lower than the input voltage.

10. The tracker module according to claim 7, wherein at least one switch included in the second converter circuit and at least one switch included in the supply modulator are included in a first integrated circuit that is arranged on the first module laminate.

11. The tracker module according to claim 8, wherein at least one switch included in the second converter circuit and at least one switch included in the supply modulator are included in a first integrated circuit that is arranged on the first module laminate.

12. The tracker module according to claim 7, wherein the second converter circuit includes a power inductor that is arranged on the first module laminate.

13. The tracker module according to claim 8, wherein the buck boost converter circuit includes:
a first power inductor,
a first input terminal configured to receive the input voltage,
a first output terminal connected to a first terminal of the supply modulator,
a first switch connected between an input end of the first power inductor and the first input terminal,
a second switch connected between the input end of the first power inductor and ground,
a third switch connected between an output end of the first power inductor and the first output terminal,
a fourth switch connected between the output end of the first power inductor and the ground, and
a first capacitor connected between a path between the third switch and the first output terminal and the ground.

14. The tracker module according to claim 8, wherein the buck converter circuit includes:
a second power inductor,
a second input terminal configured to receive the input voltage,
a second output terminal connected to a second terminal of the supply modulator,
a fifth switch connected between an input end of the second power inductor and the second input terminal,
a sixth switch connected between the input end of the second power inductor and ground, and
a second capacitor connected between a path between the second power inductor and the second output terminal and the ground.

15. A voltage supply method comprising:
converting an input voltage to a first adjustment voltage;
converting the input voltage to a second adjustment voltage lower than the input voltage; and
selectively outputting, based on an envelope signal, at least one discrete voltage of a plurality of discrete voltages that includes the first adjustment voltage and the second adjustment voltage to a first power amplifier.

16. The voltage supply method according to claim 15, further comprising outputting, based on average power, the first adjustment voltage to a second power amplifier.

17. The voltage supply method according to claim 15, further comprising:
converting the input voltage to the first adjustment voltage by following a serial data signal; and
converting the input voltage to the second adjustment voltage by following a serial data signal.

18. The voltage supply method according to claim 17, further comprising selecting the at least one discrete voltage by following a parallel data signal.

19. The voltage supply method according to claim 15, further comprising supplying the first adjustment voltage to a second power amplifier not via the supply modulator.
